(19) United States
(12) Patent Application Publication
(10) Pub. No.: US 2009/0091023 A1
(43) Pub. Date: Apr. 9, 2009

(54) Semiconductor Device Package

(75) Inventor: Masaya Tajima, Aichi (JP)

Correspondence Address: CROMPTON, SEAGER & TUFTE, LLC, 1221 NICOLLET AVENUE, SUITE 800, MINNEAPOLIS, MN, 55403-2420, US

(73) Assignee: KABUSHIKI KAISHI TOKAI RIKA DENKI SEISAKUSHO, Aichi (JP)

(21) Appl. No.: 12/244,229

(22) Filed: Oct. 2, 2008

(30) Foreign Application Priority Data
Oct. 5, 2007 (JP) 2007-261769

(51) Int. Cl. H01L 21/60; H01L 23/498

(52) U.S. Cl. 257/735; 438/124; 257/E23.068; 257/E21.506

(57) ABSTRACT

A semiconductor device package incorporating a connector that reduces manufacturing operations and enables efficient manufacturing. The semiconductor device package includes a primary molded product and a secondary molded product. The primary molded product includes a semiconductor device, a lead connected to the semiconductor device, and a plug terminal formed by at least part of the lead. The primary molded product envelops the semiconductor device and part of the lead in a first resin material. The secondary molded product envelops the primary molded product in a second resin material and includes a connector guide surrounding the plug terminal and used to guide insertion of a holder holding a socket terminal connectable to the plug terminal.

### BACKGROUND OF THE INVENTION

The present invention relates to a semiconductor device package incorporating a connector.

In the prior art, a so-called semiconductor device package covers a semiconductor device with resin to protect the semiconductor device from the ambient environment. One type of such a semiconductor device package incorporates a connector. The connector includes a plug terminal and a connector guide. The plug terminal is electrically connected to the semiconductor device by a lead or the like. The connector guide is used to guide the insertion of a holder that holds a socket terminal. Insertion of the holder into the connector guide connects the socket terminal and plug terminal. Japanese Laid-Open Patent Publication No. 2003-115630 describes such a semiconductor device package that incorporates a connector. FIG. 6 is a cross-sectional view showing the semiconductor device package described in Japanese Laid-Open Patent Publication No. 2003-115630.

As shown in FIG. 6, the semiconductor device package described in Japanese Laid-Open Patent Publication No. 2003-115630 accommodates a semiconductor device 100 in a housing formed by housing walls 110, 111, and 112, which protect the semiconductor device 100 from the ambient environment. A connector guide 130 is formed in part of the housing wall 111 to guide the insertion of a socket connector portion 200. A bonding wire 120 connects the semiconductor device 100 to a substrate line 121 (microstrip line). The side of the substrate line 121 opposite to the side connected to the bonding wire 120 is electrically connected to a basal portion of a plug terminal 131 (center conductor of a coaxial connector), which extends along the axis of the connector guide 130. The socket connector portion 200 includes a holder 210, which holds a socket terminal 201 in the center of the holder 210. In this structure, when the holder 210 is inserted into (mated with) the connector guide 130, the plug terminal 131 becomes electrically connected to the socket terminal 201 in a very stable state.

However, the connector structure described in Japanese Laid-Open Patent Publication No. 2003-115630 is limited to a structure in which a coaxial connector and coaxial cable are electrically connected to and disconnected from each other. For example, it would be difficult to apply the above-described connector structure to a semiconductor device package in which plural sets of terminals, such as those of a magnetic detector, are connected and disconnected. One example of such a semiconductor device package that incorporates a connector is shown in FIGS. 7A and 7B. FIG. 7A is a cross-sectional view taken along line 7A-7A in the plan view of FIG. 7B.

As shown in FIGS. 7A and 7B, the semiconductor device package covers a semiconductor device 300 with resin members 311, 312, and 313 so as to protect the semiconductor device 300 from the ambient environment. A connector guide 330 is formed in part of the resin member 313 to guide the insertion of a socket connector portion, which functions as a holder holding socket terminals. Bonding wires 320 connect the semiconductor device 300 to leads 321a to 321c. The leads 321a to 321c respectively include distal portions connected to basal portions of plug terminals 331a to 331c, which extend into the connector guide 330. In this structure, when the holder holding the socket terminals is inserted into the connector guide 330, the plug terminals 331a to 331c are connected to the socket terminals in a mechanically and electrically stable state.

The semiconductor device package shown in FIGS. 7A and 7B is normally manufactured by performing operations (a1) to (a4) as described below.

(a1) The resin member 311 is molded so as to envelop the semiconductor device 300 together with the bonding wires 320 and the leads 321a to 321c.

(a2) The resin member 312 is adhered to the resin member 311 in which the semiconductor device 300 and other components are enveloped.

(a3) The plug terminals 331a to 331c are inserted into the resin member 312 through insertion holes 312a. This joins the plug terminals 331a to 331c with the leads 321a to 321c, respectively.

(a4) Injection molding is performed to form the resin member 313, which includes the connector guide 330 and covers the resin members 311 and 312.

When manufacturing the semiconductor device package that incorporates a connector, the leads 321a to 321c must be electrically and mechanically connected to the plug terminals 331a to 331c. Thus, at least above operations (a2) and (a3) must be performed. This increases the number of operations required to manufacture the semiconductor device package that incorporates a connector.

### SUMMARY OF THE INVENTION

The present invention provides a semiconductor device package incorporating a connector that reduces manufacturing operations and enables efficient manufacturing.

One aspect of the present invention is a semiconductor device package incorporating a connector. The semiconductor device package includes a primary molded product and a secondary molded product. The primary molded product includes a semiconductor device, a lead connected to the semiconductor device, and a plug terminal formed by at least part of the lead. The primary molded product envelops the semiconductor device and a portion of the lead in a first resin material. The secondary molded product envelops the primary molded product in a second resin material and including a connector guide formed to surround the plug terminal and used to guide insertion of a holder holding a socket terminal that is connectable to the plug terminal.

A further aspect of the present invention is a method for manufacturing a semiconductor device package incorporating a connector. The method includes preparing a semiconductor device and a lead connected to the semiconductor device, enveloping the semiconductor device and part of the lead in a first resin material, forming a plug terminal from a portion of the lead that is exposed from the first resin material, and enveloping the first resin material in a second resin material while forming with the second resin material a connector guide used to guide insertion of a holder holding a socket terminal connectable to the plug terminal.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1A is a cross-sectional view showing a first embodiment of a semiconductor device package according to the present invention and taken along line 1A-1A in FIG. 1B;

FIG. 1B is a plan view showing the semiconductor device package of FIG. 1A;

FIGS. 2A and 2B are schematic plan views illustrating the manufacturing of the semiconductor device package shown in FIG. 1;

FIG. 3A is a schematic plane view and FIG. 3B is a schematic cross-sectional view illustrating the manufacturing of the semiconductor device package shown in FIG. 1;

FIG. 4 is a cross-sectional view showing a second embodiment of a semiconductor device package according to the present invention;

FIG. 5 is a cross-sectional view illustrating the manufacturing of the semiconductor device package shown in FIG. 4;

FIG. 6 is a cross-sectional diagram showing a prior art example of a semiconductor device package that incorporates a connector;

FIG. 7A is a cross-sectional view showing another prior art example of a semiconductor device package; and

FIG. 7B is a plan view showing the semiconductor device package of FIG. 6.

### DETAILED DESCRIPTION OF THE PREFERRED EMBODIMENTS

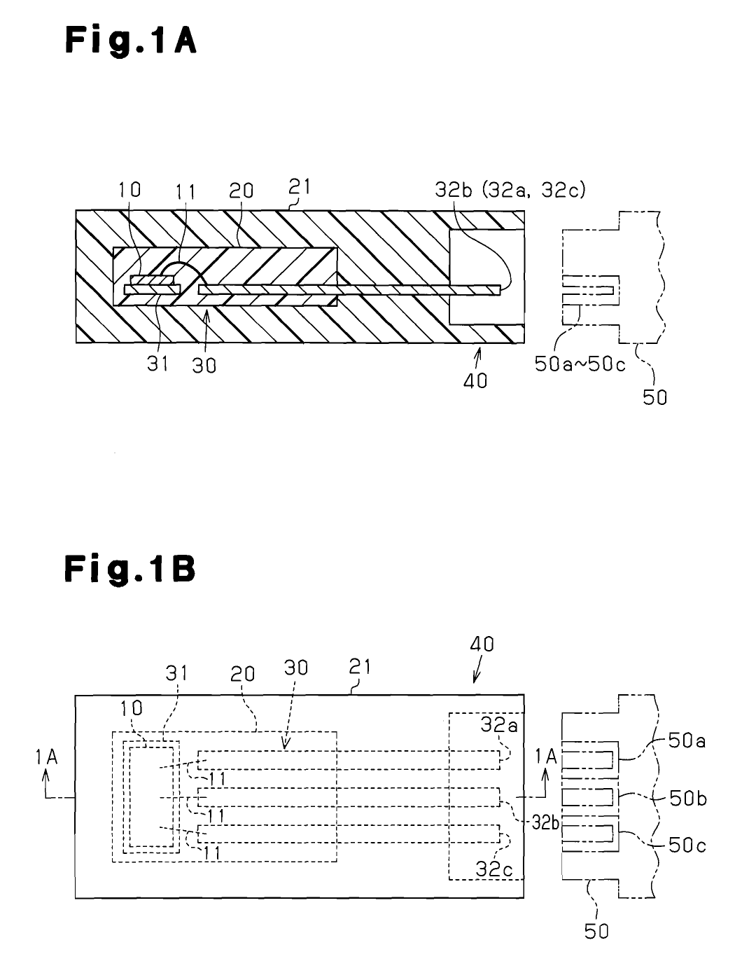

A first embodiment of a semiconductor device package that incorporates a connector according to the present invention will now be discussed with reference to FIGS. 1 to 3.

As shown in FIGS. 1A and 1B, in the first embodiment, the semiconductor device package covers a semiconductor device 10 with resin members 20 and 21 to protect the semiconductor device 10 from the ambient environment in a manner similar to the semiconductor device package shown in FIGS. 7A and 7B. The resin member 21 includes a connector guide 40, which forms part of the connector. The connector guide 40 is used to guide insertion of a holder 50, which holds socket terminals 50a to 50c (shown by broken lines in FIGS. 1A and 1B).

The semiconductor device 10 is fixed to a chip support 31 of a lead frame 30. The lead frame 30 includes leads 32a to 32c, which are electrically connected to the semiconductor device 10 by bonding wires 11. The resin member 20 is molded so as to envelop the semiconductor device 10, the bonding wires 11, and the leads 32a to 32c. The molding of the resin member 20 forms a primary molded product. The leads 32a to 32c are partially exposed from the primary molded product. The exposed portions of the leads 32a to 32c extend through the resin member 21, which serves as a secondary molded product, to the connector guide 40.

The connector guide 40 of the resin member 21 includes a hollow portion located rightward from the resin member 20, as viewed in FIG. 1A. The leads 32a to 32c extend into the hollow portion of the connector guide 40. In the first embodiment, the leads 32a to 32c in the connector guide 40 are used as plug terminals of the connector. Accordingly, the leads 32a to 32c are connectable to the socket terminal 50a to 50c. Further, the leads 32a to 32c and the connector guide 40 form the connector of the semiconductor device package. When the holder 50 holding the socket terminals 50a to 50c is inserted into the connector guide 40, the leads 32a to 32c are respectively connected to the socket terminals 50a to 50c in a mechanically and electrically stable state. In the semiconductor device package, the leads 32a to 32c have a thickness of 0.4 mm to 0.64 mm and therefore have the rigidity required for plug terminals.

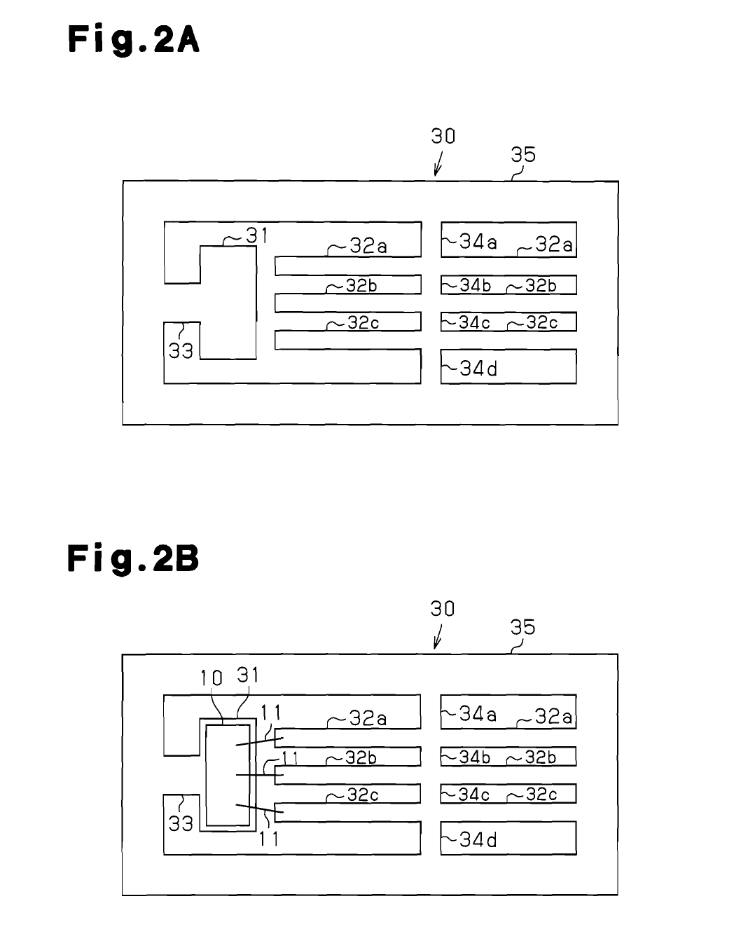

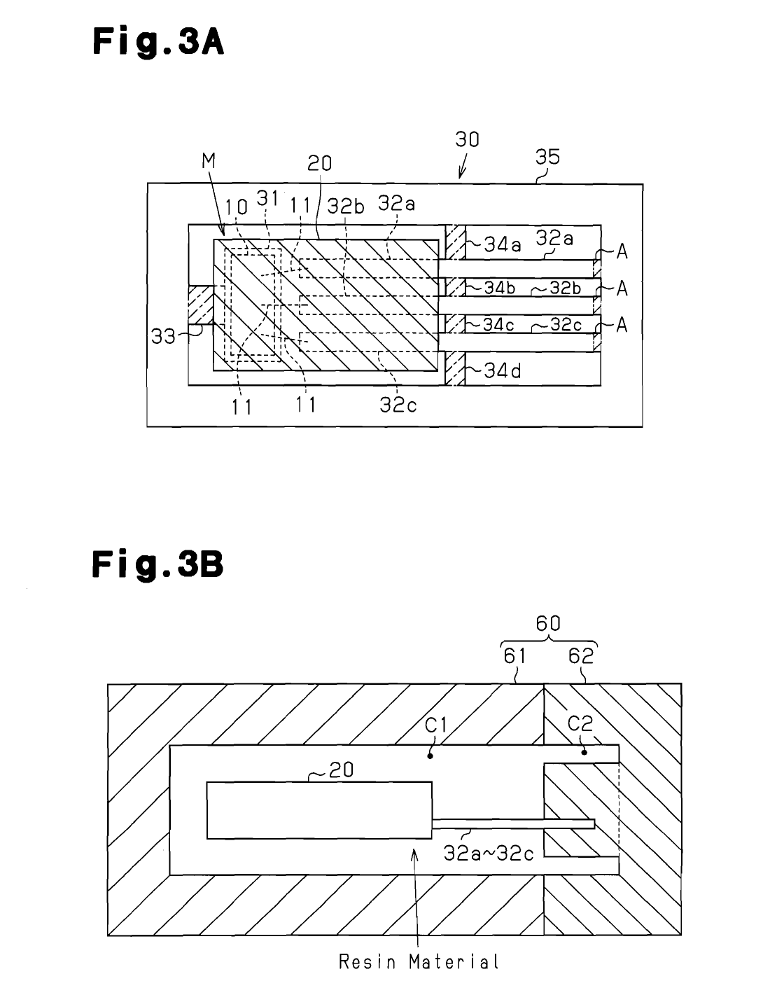

FIGS. 2A, 2B, 3A, and 3C are diagrams showing the manufacturing of the semiconductor device package incorporating a connector. FIGS. 2A, 2B, and 3A are enlarged views showing the portion of a lead frame 30 that corresponds to a single semiconductor device package.

The lead frame 30 shown in FIG. 2A includes a chip support 31 and the plurality of leads 32a to 32c, which are spaced from the chip support 31. The lead frame 30 includes an outer frame 35, which is connected to the chip support 31 by an extension 33. The leads 32a to 32c each include a distal end and a middle section connected to the outer frame 35. The middle sections of the leads 32a to 32c are connected to the outer frame 35 by extensions 34a to 34d.

Referring to FIG. 2B, when manufacturing the semiconductor device package incorporating a connector, the semiconductor device 10 is die-bonded to the chip support 31. Then, the leads 32a to 32c are wire-bonded to the semiconductor device 10. This electrically connects the leads 32a to 32c and the semiconductor device 10 with the bonding wires 11.

Next, referring to FIG. 3A, the lead frame 30 is set, for example, in a mold. A first resin material is charged into the mold to form a resin molding region M, which is indicated by the solid hatching lines in FIG. 3A. The resin molding region M defines the resin member 20. The resin material is hardened by undergoing thermosetting. This integrally molds and envelops the semiconductor device 10, the bonding wires 11, and part of the leads 32a to 32c in the resin member 20. Then, lead cutting is performed to punch out portions indicated by the broken hatching lines in FIG. 3A with a press or the like. That is, sections A, which connect the leads 32a to 32c to the outer frame 35, and the extensions 33 and 34a to 34d are punched out by a press or the like. This forms the portion of the semiconductor device package shown in FIG. 1 that excludes the resin member 21. This portion is referred to as the primary molded product. In this state, the leads 32a to 32c are partially exposed from the primary molded product.

After the primary molded product of the semiconductor device package is completed, the resin member 21 is molded around the primary molded product. The resin member 21 is referred to as the secondary molded product. FIG. 3B shows a mold 60 used to form the secondary molded product. The mold 60 includes a first mold part 61 and a second mold part 62. The first mold part 61 includes a cavity C1, which is shaped in correspondence with the portion of the resin member 21 that accommodates the primary molded product of the semiconductor device package. The second mold part 62 includes a cavity C2, which is shaped in correspondence with the portion of the resin member 21 corresponding to the connector guide 40. To mold the resin member 21, the primary molded product of the semiconductor device package is set in the mold 60 in the state shown by FIG. 3B. Then, a second resin material is charged into the cavities C1 and C2. The resin material is hardened by undergoing thermosetting. This completes the semiconductor device package that incorporates a connector as shown in FIG. 1.

The structure of the semiconductor device package incorporating a connector simplifies the manufacturing process as compared with the prior art. More specifically, in the prior art, to join the leads and plug connector, two operations are performed. The first operation is attaching a predetermined resin member to the primary molded product of the semiconductor device package. The second operation is joining the leads of the semiconductor device package to the plug terminals. In the first embodiment, these two operations are not performed when manufacturing the semiconductor device package. Still, the semiconductor device package includes the plug terminals and the connector guide 40, which is used to guide the insertion of the holder 50 for the socket terminals 50a to 50c that are connected to the leads 32a to 32c (plug terminals). Accordingly, fewer operations are performed when manufacturing the semiconductor device package of the first embodiment in comparison with the prior art.

In the first embodiment, the semiconductor device package has the advantages described below.

(1) The primary molded product of the semiconductor device package includes the leads 32a to 32c, each having a portion forming a plug terminal of the connector. The secondary molded product of the semiconductor device package is formed so as to entirely envelop the primary molded product in resin material in a state in which the connector guide 40 surrounds the leads 32a to 32c. Further, the secondary molded product includes the connector guide 40, which is used to guide the insertion of the holder 50 holding the socket terminals 50a to 50c that are connected to the leads 32a to 32c. This structure eliminates the need to connect the leads of the semiconductor device package with plug terminals as in the manufacturing process of the prior art. Thus, the number of manufacturing operations is reduced, and productivity is increased.

(2) The leads 32a to 32c are set to have a thickness of 0.4 mm to 0.64 mm. Thus, even though the leads 32a to 32c are used as the plug terminals, the rigidity and reliability required for a plug terminal of a connector is obtained.

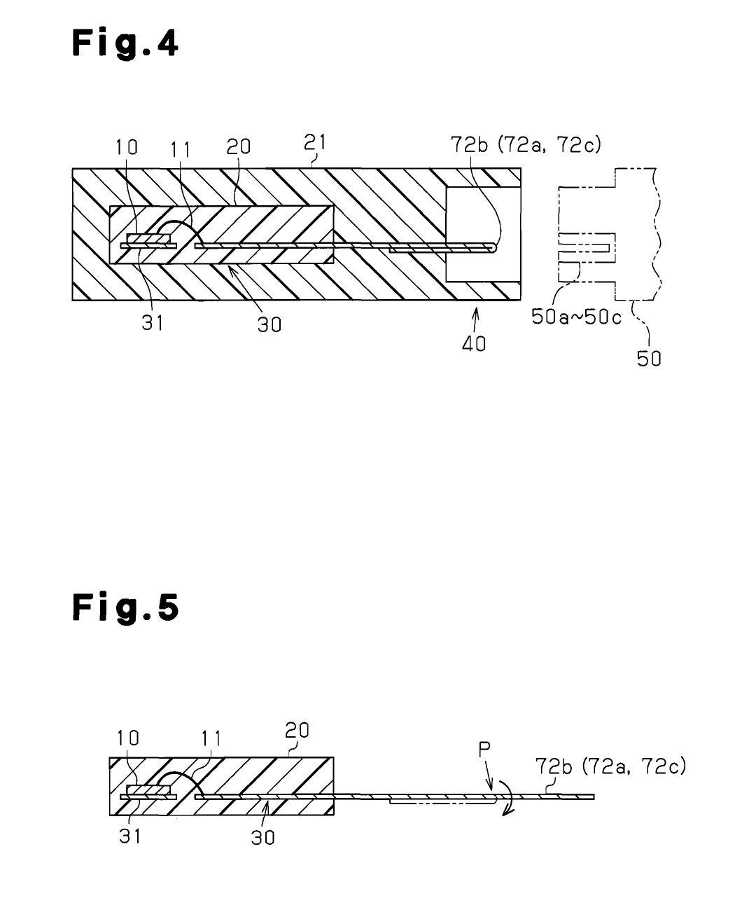

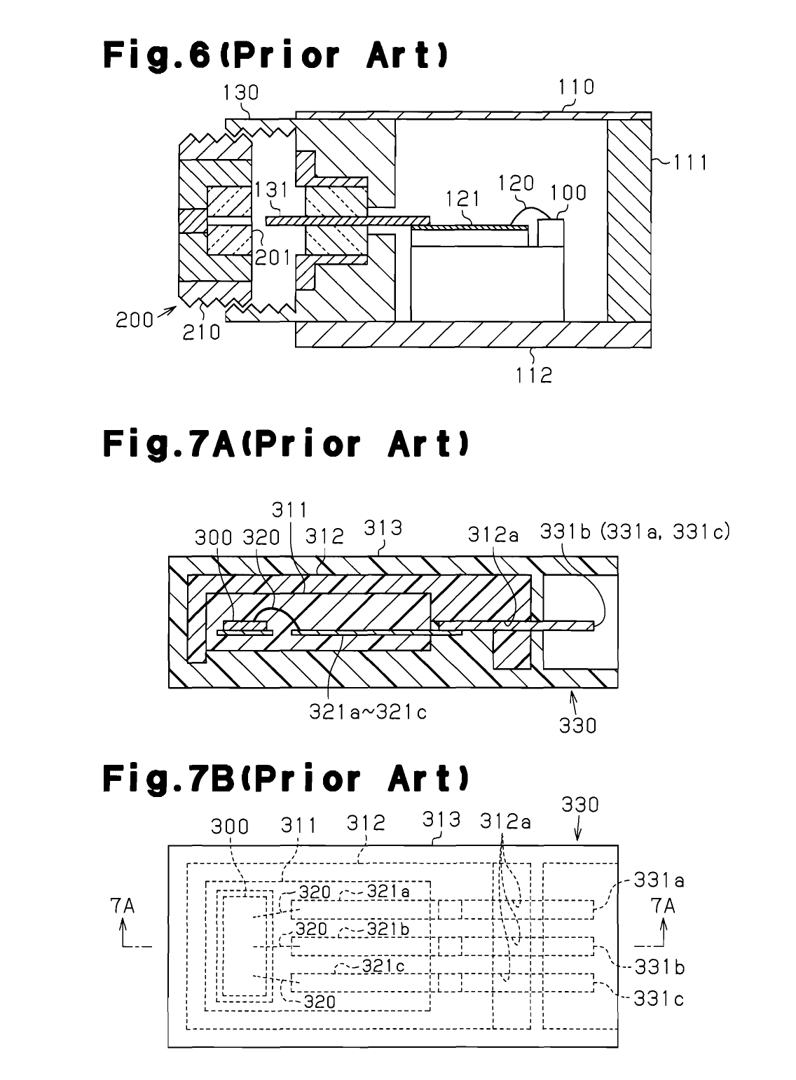

A second embodiment of a semiconductor device package according to the present invention will now be discussed with reference to FIGS. 4 and 5. In the second embodiment, the structure of the semiconductor device package is basically the same as that shown in FIGS. 1A and 1B. Here, FIG. 4, which is a cross-sectional view showing the structure of the semiconductor device package corresponds to FIG. 1A. In FIG. 4, the same reference numerals are given to those components that are the same as the corresponding components of FIG. 1A. Such components will not be described, and the following description will center on differences between the first and second embodiments.

Due to the recent demand for semiconductor device packages that are more miniaturized and have a higher level of integration, in a semiconductor device package that incorporates a connector, which is used to connect and disconnect a plurality of terminals, such as a magnetic detector, a lead frame is required to have leads with a smaller width and pitch. However, when setting the thickness of such leads to, for example, 0.2 mm to 0.32 mm to cope with such demands, the rigidity would be insufficient when using the leads as plug terminals.

As shown in FIG. 4, in the second embodiment, the semiconductor device package includes leads 72a to 72c, which are longer than the leads 32a to 32c used in the semiconductor device package of the first embodiment. The leads 72a to 72c are bent in the connector guide 40 so that distal portions of the leads 72a to 72c are accommodated in the resin member 21. That is, the leads 72a to 72c are each folded and doubled over in the connector guide 40. Thus, even if the leads 72a to 72c are set to have a thickness of 0.2 mm to 0.32 mm, the exposed and folded portions of the leads 72a and 72c in the connector guide 40 and functioning as the plug terminals would have a thickness that is two times greater than the thickness of the leads 72a to 72c, that is, a thickness of 0.4 mm to 0.64 mm. This would obtain the rigidity required for plug terminals.

The process for manufacturing the semiconductor device package will now be described with reference to FIG. 5. This process is similar to the process illustrated in FIGS. 2A to 3B. FIG. 5 illustrates an operation that is performed subsequent to the operation shown in FIG. 3A. The operation of FIG. 5 is performed during the formation of the primary molded product.

As shown in FIG. 5, after lead cutting the lead frame 30 shown in FIG. 3A, portions of the long leads 72a to 72c exposed from the resin member 20 are folded back from a folding point P as shown by the broken lines in the drawing. The folding doubles over the right part of the leads 72a to 72c as viewed in FIG. 5 to form the plug terminals. Then, when forming the secondary molded product, a mold corresponding to the mold 60 is used to mold the resin member 21 around the plug terminals. This completes the semiconductor device package that incorporates a connector.

The second embodiment adds a new operation in which the leads 72a to 72c are folded when manufacturing the semiconductor device package that incorporates a connector. However, the two operations of adhering and bonding as in the prior art process for manufacturing a semiconductor device package do not have to be performed. This reduces the total number of manufacturing operations.

In the second embodiment, the semiconductor device package has the advantages described below.

(3) The long leads 72a to 72c are folded to form the plug terminals. Thus, even though the leads 72a to 72c do not have the thickness and rigidity required for use as plug terminals, the folded overlapping portions of the leads 72a to 72c ensures the thickness and rigidity required for plug terminals. This maintains reliability as a connector in an optimal manner.

(4) The long leads 72a to 72c are folded to form the plug terminals when the primary molded product is formed. Further, the connector guide 40, which is used to guide the insertion of the holder 50 that holds the socket terminals 50a to 50c connected to the plug terminals, is formed from a resin material in a state surrounding the plug terminals when the secondary molded product is formed. Accordingly, the connector guide 40 and the leads 72a to 72c, which include portions used as the plug terminals, form the connector of the semiconductor device package. Thus, even though a new operation is added in which the leads 72a to 72c are folded when manufacturing the semiconductor device package that incorporates a connector, the bonding of the leads and the plug terminals as in the prior art process for manufacturing a semiconductor device package does not have to be performed. This reduces the manufacturing operations in total and improves the productivity.

It should be apparent to those skilled in the art that the present invention may be embodied in many other specific forms without departing from the spirit or scope of the invention. Particularly, it should be understood that the present invention may be embodied in the following forms.

In the second embodiment, the leads 72a to 72c are folded and doubled over to fold the plug terminals. However, depending on the thickness and rigidity of the leads, the leads may be folded to be tripled over when forming the plug terminals. This would enable plug terminals for a connector to be formed from leads having a thickness of less than 0.2 mm to 0.32 mm. It is only required that the leads in a primary molded product of a semiconductor device package be used to form the plug terminals of a connector.

In the description of each of the above embodiments, there is no reference to a surface treatment that is performed on the leads 32a to 32c and 72a to 72c. However, if the socket terminals 50a to 50c are plated with tin or gold, it is preferable that the leads 32a to 32c and 72a to 72c also be plated with tin or gold.

The present examples and embodiments are to be considered as illustrative and not restrictive, and the invention is not to be limited to the details given herein, but may be modified within the scope and equivalence of the appended claims.

What is claimed is:

1. A semiconductor device package incorporating a connector, the semiconductor device package comprising:
a primary molded product including a semiconductor device, a lead connected to the semiconductor device, and a plug terminal formed by at least part of the lead, with the primary molded product enveloping the semiconductor device and a portion of the lead in a first resin material; and
a secondary molded product enveloping the primary molded product in a second resin material and including a connector guide formed to surround the plug terminal and used to guide insertion of a holder holding a socket terminal that is connectable to the plug terminal.

2. The semiconductor device package according to claim 1, wherein the lead has a thickness of 0.4 mm to 0.64 mm.

3. The semiconductor device package according to claim 1, wherein the plug terminal is formed by folding a portion of the lead that is exposed from the first resin material.

4. The semiconductor device package according to claim 3, wherein the lead has a thickness of 0.2 mm to 0.32 mm.

5. The semiconductor device package according to claim 1, wherein the plug terminal and the connector guide form the connector.

6. A method for manufacturing a semiconductor device package incorporating a connector, the method comprising:
preparing a semiconductor device and a lead connected to the semiconductor device;
enveloping the semiconductor device and part of the lead in a first resin material;
forming a plug terminal from a portion of the lead that is exposed from the first resin material; and
enveloping the first resin material in a second resin material while forming with the second resin material a connector guide used to guide insertion of a holder holding a socket terminal connectable to the plug terminal.

7. The method according to claim 6, wherein the lead has a thickness of 0.4 mm to 0.64 mm.

8. The method according to claim 6, wherein said forming a plug terminal includes folding a portion of the lead that is exposed from the first resin material.

9. The method according to claim 8, wherein the lead has a thickness of 0.2 mm to 0.32 mm.

10. The method according to claim 6, further comprising forming the connector with the plug terminal and the connector guide.
